(19) United States
(12) Patent Application Publication
(10) Pub. No.: US 2020/0354854 A1
(43) Pub. Date: Nov. 12, 2020

(54) METHOD OF PRODUCING PARTICLE-SHAPED DIAMOND SINGLE-CRYSTAL USING CHEMICAL VAPOR DEPOSITION

(71) Applicant: KOREA INSTITUTE OF SCIENCE AND TECHNOLOGY, Seoul (KR)

(72) Inventors: Jae Kap LEE, Seoul (KR); Kwang Koo JEE, Seoul (KR)

(73) Assignee: KOREA INSTITUTE OF SCIENCE AND TECHNOLOGY, Seoul (KR)

(21) Appl. No.: 16/862,018

(22) Filed: Apr. 29, 2020

(30) Foreign Application Priority Data
May 8, 2019 (KR) 10-2019-0053848

(51) Int. Cl. C30B 25/16; C30B 29/04; C30B 29/66; C30B 25/08

(52) U.S. Cl. CPC C30B 25/16; C30B 25/08; C30B 29/66; C30B 29/04

(57) ABSTRACT

According to one aspect of the present invention, a method of producing a particle-shaped diamond single-crystal using chemical vapor deposition (CVD). According to one embodiment, the method includes disposing a single-crystal diamond grit seed on a stage substrate in a diamond synthesis chamber and three-dimensionally growing the single-crystal diamond grit seed to a particle-shaped diamond single-crystal by introducing a source gas into the chamber.

### CROSS-REFERENCE TO RELATED APPLICATION(S)

This application claims the benefit under 35 USC § 119(a) of Korean Patent Application No. 10-2019-0053848, filed on May 8, 2019, in the Korean Intellectual Property Office, the entire disclosure of which is incorporated herein by reference for all purposes.

### BACKGROUND

### 1. Field

The following description relates to a method of producing single-crystal diamond by chemical vapor deposition (CVD), and more specifically, to a method of producing particle-shaped single-crystal diamond of a relatively large size by growing grit-shaped diamond seed of a minute size using CVD.

### 2. Description of Related Art

Diamond was successfully synthesized under a high pressure-high temperature (HPHT) condition (1500° C. and ˜50,000 atm) by General Electric (GE) in the U.S. in 1955. Diamond produced by the HPHT method is a particle in the form of grit having a size (diameter) of about ˜0.5 mm. The diamond single-crystal grit has a cuboctahedron shape, in which (100) plane and (111) plane alternately appear on the surface, as shown in FIG. 13. In the 1970s, the HPHT single-crystal diamond growth method was proposed using the diamond single-crystal grit as a seed. Single-crystal diamond plates of about 1×1 cm² with a thickness of several hundreds of μm, which is a slice of single-crystal diamond grown, are producible. In the 1980s, chemical vapor deposition (CVD) methods for synthesis of diamond was reported. In the CVD method, diamond is synthesized as a “polycrystalline film.” In the 2000s, a “CVD technique for the growth of single-crystal diamond” was proposed. Here, HPHT diamond plates are served as a seed. CVD diamond can be transparent like natural diamond because the synthesis is performed in a vacuum chamber free from nitrogen, while HTHT diamond reveals yellow color due to nitrogen atoms, which were incorporated during its growth under atmosphere ambient. For CVD growth of single-crystal diamond, a plasma process, generally a microwave plasma is used.

CVD growth of single-crystal diamond occurs one dimensionally, i.e., z-direction, thus diamond plates are served as a seed which is HPHT SCD plate of about 1×1 cm² (about 0.5 mm in thickness). Such “one-dimensional growth”, in which the thickness is increased, results in a tendency that the dimension of the seed decreases with the increase of thickness due to variation of parameters. This is the reason why the dimension of SCD cannot be enlarged in the CVD approach. Meanwhile, the CVD grown (thick) SCD in the shape of a plate (about 1×1×1 cm³) may be used as an electronic material or made into gems or tools. The conventional plate-shaped CVD SCD, when made into gems or tools, must be cut into about 5 mm pieces and processed, which results in the loss of large portion of the raw SCD.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The present invention provides a method of producing a particle-shaped single-crystal diamond (SCD) via three-dimensional growth using chemical vapor deposition (CVD), wherein high pressure and high temperature (HPHT) diamond grits are used as the seed.

According to one aspect of the present invention, there is provided a method of producing a particle-shaped SCD using CVD.

The method of producing a particle-shaped SCD includes disposing a HPHT diamond seed (grit) (about 0.5 mm in size) on a substrate in a vacuum chamber and three-dimensionally growing the seed to a particle-shaped SCD (about 5 mm in size) in a CVD condition for the synthesis of diamond.

The HPHT SCD seed may exhibit a cuboctahedron shape consisting of (100) and (111) planes.

The growth of the seed may occur under a condition of ‘near <100> texture’ or ‘near <110> texture’, where (100) planes of diamond grows dominantly and are generally free from secondary nucleation. The condition is ideal for the growth of SCD.

The seed may be a HPTH diamond grit, or natural diamond.

The substrate may have a plurality of grooves for seeds to be disposed at a predetermined spacing from one another for their ideal growth.

The key parameters for the CVD growth of diamond are the concentration of methane in hydrogen and temperature, while other parameters, pressure and flow rate of the gases, range from 10 Torr to 500 Torr and from 10 sccm to 1,000 sccm, respectively.

We provide an empirical formula for the growth of SCD (without second nucleation) below,

y≤0.125(x−40)+5 Expression 1:

y: Vol % of methane in hydrogen gas

x: T+40 to T+120 (T is the temperature at which the <100> texture evolves).

Other features and aspects will be apparent from the following detailed description, the drawings, and the claims.

### BRIEF DESCRIPTION OF THE DRAWINGS

FIG. 1 shows variation of the texture of diamond film with deposition temperature.

FIG. 2 shows a scanning electron microscope (SEM) image for SCD grown in present invention.

FIG. 3 shows the zone, free from secondary nucleation in the present invention. ‘0’ indicates the zone free from secondary nucleation.

FIG. 4 shows a schematic depicting a CVD chamber for the growth of SCD and SEM images showing a SCD grit seed (left) and a particle-shaped SCD grown (right) in the present invention.

FIG. 5 is a schematic depicting multi(7)-cathode direct current plasma assisted CVD (MCDC-PACVD) apparatus according to one embodiment of the present invention.

FIGS. 6 and 7 are schematics depicting the arrangement of diamond seeds on a substrate and an anode of the MCDC PACVD apparatus shown in FIG. 5.

FIG. 8 is a schematic showing the arrangement of seven cathodes of the MCDC PACVD apparatus shown in FIG. 5.

FIG. 9 is a schematic depicting structure of the cathode feedthrough of the MCDC PACVD apparatus shown in FIG. 5.

FIGS. 10 and 11 are schematics showing the arrangement of the cathodes of the MCDC PACVD apparatus shown in FIG. 5.

FIG. 12 shows a schematic depicting SCD grit with a cuboctahedron shape.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the sizes of elements may be exaggerated or reduced for convenience of explanation.

According to a method of producing a particle-shaped SCD in accordance with one embodiment of the present invention, SCD grits are disposed as seeds on a substrate in a plasma assisted CVD (PACVD) chamber for the synthesis of diamond.

The SCD grit seeds may be of HPHT or natural diamond with a cuboctahedron shape consisting of (100) and (111) planes. The size of the single-crystal grit seed may be, for example, 0.5 mm or less.

A stage substrate on which receiving grooves for diamond seeds are created is prepared. Here, the width and depth of the receiving grooves and the interval between the receiving grooves can be controlled in consideration of a target size of single-crystal diamond. For example, the interval between the receiving grooves should be enough wide so that the growth of the diamond seeds does not interfere with each other. The stage substrate may be made of high melting point metal, for example, molybdenum (Mo), tantalum (Ta), or tungsten (W).

The stage substrate where the single-crystal diamond seeds are placed in the receiving grooves is loaded in the CVD chamber. The three-dimensional growth of the single-crystal grit seed is performed in a CVD condition.

According to one embodiment of the present invention, the diamond seed is a three-dimensional particle (for example a HPHT grit).

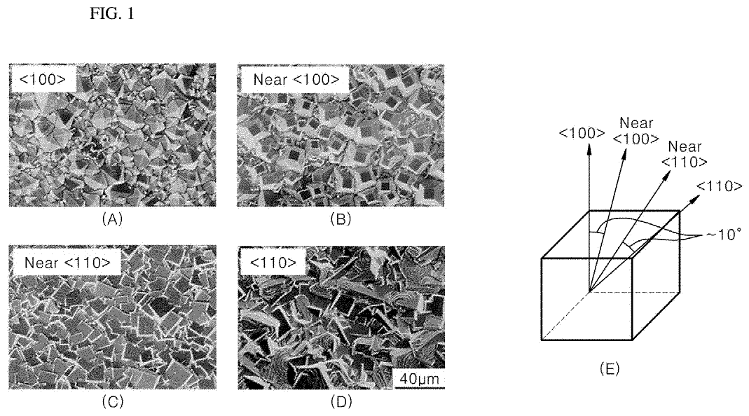

In this case, according to a technical idea of the present invention, in order to maintain the three-dimensional growth, ‘near <100> texture’ condition is kept, where the growth is dominated by (100) plane on which secondary nucleation is prohibited. Here, the near <100> texture means that the texture orientation is slightly deviated by ˜10 degrees with respect to <100> direction. (E) of FIG. 1 shows the near <110> orientation, together with the near <100> orientation.

The near <100> texture condition for the “three-dimensional growth of the seed” may be implemented by appropriately controlling deposition parameters, gas composition (generally the concentration of methane in hydrogen) and temperature.

In the present invention, CVD equipment for the growth of the particle-shaped diamond single-crystal may be microwave plasma assisted CVD (MW PACVD) or direct current plasma CVD (DC CVD). Hereinafter, a method for the three-dimensional growth of single-crystal diamond using multi (7)-cathode DC plasma-assisted CVD (MDDC PACVD) will be described. The MCDC PACVD apparatus uses typically seven cathodes.

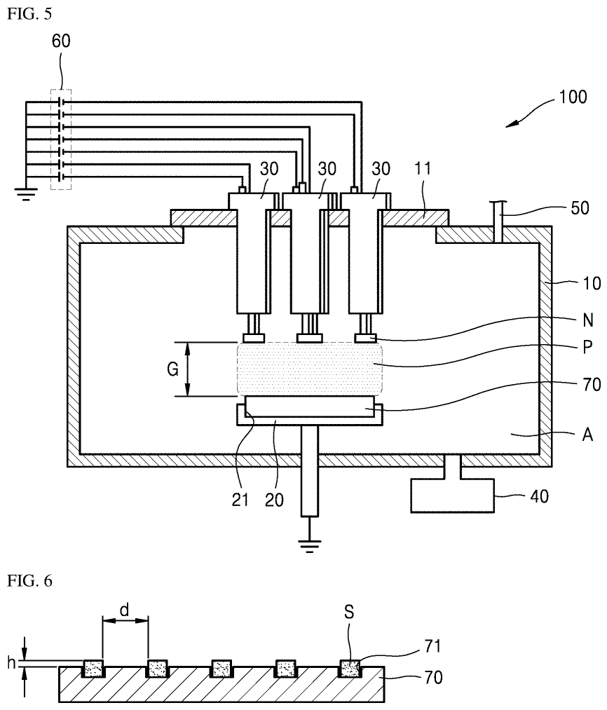

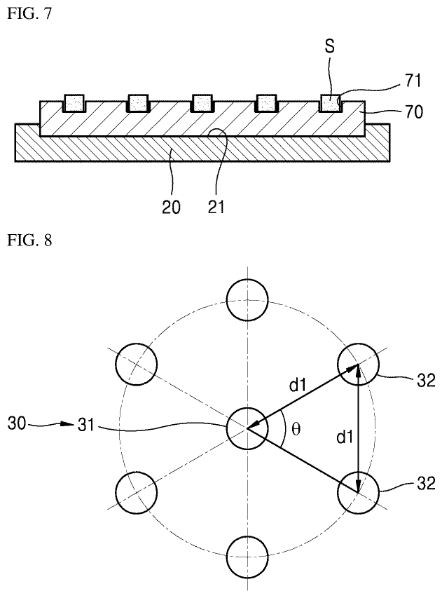

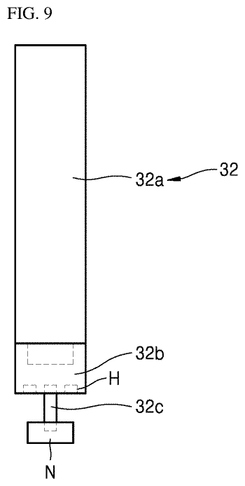

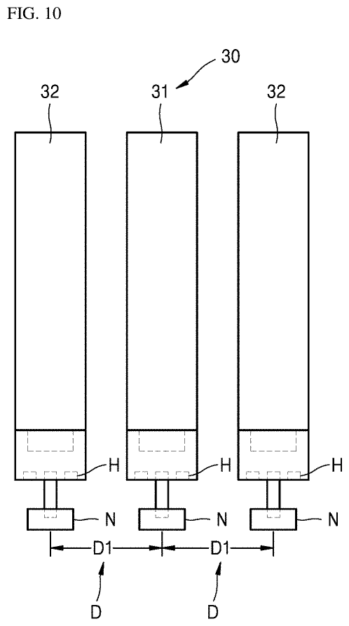

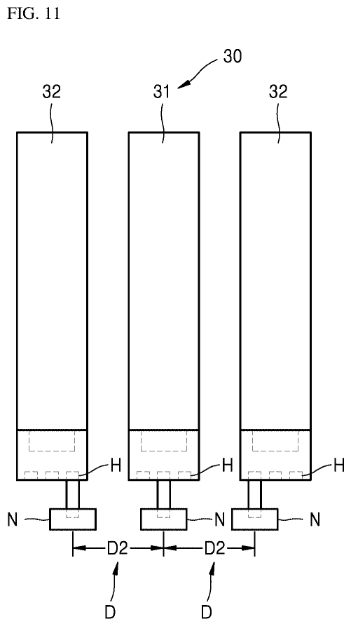

FIG. 5 is a cross-sectional view schematically showing a MCDC PACVD apparatus 100, and FIGS. 6 and 7 are cross-sectional views schematically showing a stage substrate 70 and an anode portion 20 of the MCDC PACVD apparatus 100. FIG. 8 is a cross-sectional view schematically showing the arrangement of seven cathodes of the MCDC PACVD apparatus 100 of FIG. 5, and FIG. 9 is a cross-sectional view schematically showing a cathode 32 of the MCDC PACVD apparatus 100 of FIG. 5. FIGS. 10 and 11 are cross-sectional views schematically showing a way of controlling the inter-cathode distance D between cathodes N. As shown in FIG. 5, the MCDC PACVD apparatus 100 according to one embodiment of the present invention may include a CVD chamber 10, the anode portion 20, cathode portions 30, a vacuum pump 40, a gas inlet 50, a DC power supply 60, and a stage substrate 70.

As shown in FIG. 5, the CVD chamber 10 may have an inner space A in which plasma is generated and a single-crystal grit seed S is disposed. More specifically, the CVD chamber 10 may generate a plasma P between the anode portion 20 and the cathode portions 30 installed inside the inner space A.

Also, the CVD chamber 10 may have the vacuum pump 40 the gas inlet 50 Furthermore, although not illustrated, a gate capable of loading or unloading the stage substrate 70 that accommodates a single-crystal grit seed S to the inner space A may be formed on one side surface of the CVD chamber 10.

The stage substrate 70, which the single-crystal grit seeds S are seated, is placed on the anode 20 grounded. Here the plasma is generated between the substrate stage and seven cathodes. The cathodes are kept at high temperature above 2000° C., thus are made from tantalum with a high melting temperature.

In addition, as shown in FIG. 5, the cathode portions 30 may be installed on an upper portion of the CVD chamber 10 to face the anode portion 20 by which the stage substrate 70 is supported and may be formed by a combination of a plurality of cathode devices connected to DC power supply devices 60 independent of each other. In this case, the cathode portions 30 may be installed on a top plate 11 formed on an upper surface of the CVD chamber 10 such that maintenance of the cathode portions 30 or maintenance of the interior of the chamber 10 can be easily performed by only disassembling the top plate 11.

More specifically, the anode portion 40 and the cathode portions 30 are installed to face each other at a predetermined spaced distance G on a lower portion and the upper portion of the inner space A of the CVD chamber 10 which is maintained in a vacuum state by the vacuum pump 40. Also, the gas inlet 50 for introducing the source gas may be installed on one side of the CVD chamber 10 and the vacuum pump 40 for controlling a plasma reactive pressure may be installed on the other side of the CVD chamber 10. At this time, the cathode portions 30 installed on the CVD chamber 10 may move up and down to control the spaced distance G to the top surface of the stage substrate 70 seated on the anode portion 20, and more preferably, the spaced distance G may be adjusted in a range from 30 mm to 50 mm in which the single-crystal grit seeds S accommodated in the stage substrate 70 can be uniformly grown. In the MCDC PACVD apparatus 100, the spaced distance G between the cathode portions 30 and the anode portion 20 may act as one of important variables, and the spaced distance G may be set to be adjustable within the above-described range even during synthesis of single-crystal diamond.

In addition, the combinations of cathode devices of the cathode portions 30 may each be connected to each of the DC power supply devices 60 independent of each other. This may be to prevent a phenomenon that the current flows to only one cathode N of each cathode device if a difference of electric resistance between the cathode N of each cathode device and the anode portion 20 occurs when the combinations of the cathode devices are connected to the same DC power supply device.

For example, if the current flows to only some cathodes N of each cathode device of the cathode portions 30, plasma is formed only between the cathode N through which the current flows and the anode portion 20, so that the size of plasma P is reduced and the shape thereof is slanted toward one side and thus uniform growth of the plurality of single-crystal grit seeds S accommodated in the stage substrate 70 may be impossible.

Therefore, each of the cathode devices of the cathode portions 30 may be connected to each of the DC power supply devices 60 independent of each other and may adjust the current density individually so that the uniform current flows between the cathode N of each cathode device and the anode portion 20, thereby inducing uniform generation of the plasma P over a large area.

The stage substrate 70 accommodating the single-crystal grit seeds S and the structure of the anode portion 20 supporting the stage substrate 70 will be described in more detail. As shown in FIG. 6, the stage substrate 70 may be in the form of a disk shape and a plurality of seed receiving grooves 71 in which the single-crystal grit seeds S can be seated may be disposed on a top surface of the stage substrate 70 at a predetermined spacing. For example, the receiving groove 71 of the stage substrate 70 may accommodate a single-crystal grit seed S produced by a high temperature high pressure method.

In this case, the width, height, and spacing of the receiving grooves 71 may be appropriately designed in consideration of a size of finally grown SCD particles. For example, the spacing D of the receiving grooves may be set in consideration of a widthwise size of the final SCD particles, and may be designed to be, for example, at least 1 mm or more greater than the widthwise size of the final SCD particles.

In order to allow the DC plasma P to be stably generated and to facilitate the growth of the single-crystal grit seed S, the height of the receiving groove 71 is designed to have a smaller value compared to the height of the single-crystal grit seed S such that the single-crystal grit seed S can have a predetermined height h protruding from the top surface of the stage substrate 70 when accommodated in the receiving groove 71. In this case, the stage substrate 70 in contact with the plasma P serves as an electrode (anode) together with the anode portion 20, and hence the height h of the single-crystal grit seed S protruding from the top surface of the stage substrate 70 may be preferably 0.5 mm or less such that the plasma P can be stably generated.

For example, when the protruding height H of the single-crystal grit seed S exceeds 0.5 mm, the stage substrate 70 serving as an electrode may be covered by diamond seeds so that loss of plasma P may occur. Therefore, the single-crystal grit seed S is preferably formed to have a protruding height h of 0.5 mm or less. Accordingly, the depth of the receiving groove 71 of the stage substrate 70 may be set to fall within a range from 0.1 mm to 10 mm to allow the single-crystal grit seed S to be formed to have the protruding height h of 0.5 mm or less.

As shown in FIG. 7, the anode portion 20 is formed in a disk shape with a diameter larger than the diameter of the stage substrate 70 and has, on the top surface thereof, a seating groove portion 21 in a shape corresponding to at least a part of the stage substrate 70, and at least the part of the stage substrate 70 may be seated in the seating groove portion 21. As such, the stage substrate 70 may be formed to be independent of the anode portion 20 so as to be easily replaced depending on the growth status of the single-crystal grit seeds S accommodated in the seed receiving grooves 71.

In addition, the MCDC PACVD apparatus 100 may control the spaced distance D between the cathodes N of each of the combinations of cathode devices of the cathode portions 30 so that uniformity of the plasma P can be maintained according to the change of synthesis conditions in a MCDC PACVD diamond synthesis method.

More specifically, as shown in FIG. 8, in the combinations of the cathode devices of the cathode portion 30, the plurality of cathode devices 32 may be spaced radially from one another by a predetermined equal angle θ about one center cathode device 31 formed at a central portion of the arrangement. For example, the cathode portions 30 may each be formed by a combination of seven cathode devices, and six cathode devices 32 are spaced radially from one another by an equal angle of 60 degrees about one central cathode device 31 formed in the central portion.

In this case, the central cathode device 31 and each of the cathode devices 32 may be formed at a center-to-center spacing d1 of 43 mm to 47 mm from each other and it may be preferable to form the same center-to-center spacing d1 for generation of uniform plasma P. The number or arrangement of the cathode devices of the cathode device combination of the cathode portions 30 is not limited to the above configuration and may be adjusted variously depending on the single-crystal diamond synthesis conditions or the area of the stage substrate 70 accommodating the plurality of single-crystal grit seeds S.

The structure of each of the cathode devices 32 will be described in detail. As shown in FIG. 9, the cathode device 32 is installed in a top plate 11 in an upper portion of the CVD chamber 10 and may be composed of a cathode body 32a formed in a cylindrical shape and connected to the DC power supply device 60, a cathode holder 32b formed in a cylindrical shape with the same diameter as the cathode body 32a and screwed to an end of the cathode body 32a, a cathode suspension rod 32c formed in a rod shape with a diameter smaller than that of the cathode holder 32b and screwed to an end of the cathode holder 32b, and the cathode N formed in a cylindrical shape with a diameter greater than the diameter of the cathode suspension rod 32c and screwed to an end of the cathode suspension rod 32c.

For example, the cathode N may be kept suspended in the inner space A of the CVD chamber 10 by the cathode suspension rod 32c formed on a lower part of the cathode body 32a. Also, the cathode body 32a may have a metal shielding film formed on an outer surface thereof or may be covered by insulating ceramics, such as boron nitride, to prevent generation arc between the cathode body 32a and a body of the CVD chamber 10 grounded and having positive polarity or the anode portion 20, and a coolant passage through which a coolant flows may be formed inside of the cathode body 32a to allow the coolant to circulate inside.

The cathode suspension rod 32c formed between the cathode body 32a and the cathode N and connecting them may be formed in a rod shape with a diameter smaller than the cathode body 32a or the cathode N, thereby effectively suppressing heat conduction from the cathode N in a high-temperature state to the cathode body 32a cooled by the coolant when the plasma P is generated. For example, the cathode N may be formed in a cylindrical shape having a diameter of 5 mm to 10 mm and the cathode suspension rod 32c may be formed in a rod shape having a diameter of 2 mm to 4 mm and a length of 10 mm to 20 mm.

In this case, the cathode N and the cathode suspension rod 32c may be preferably made of high melting point carbide, such as tungsten carbide, tantalum carbide, titanium carbide, or the like, or a high fusion point metal material, such as tungsten, tantalum, or the like, so that deformation does not occur at a high temperature of 2000° C. or higher when the plasma P is generated.

Moreover, as shown in FIG. 5, the cathode suspension rod 32c may be coupled to a lower part of the cathode body 32a via the cathode holder 32b and the cathode holder 32b may have a plurality of screw hole portions H into which the cathode suspension rod 32c is screw-coupled, so that the coupling position of the cathode suspension rod 32c can be adjusted variously.

More specifically, as shown in FIG. 8, the plurality of screw hole portions H may be arranged radially around one central screw hole portion CH formed in a center portion of a lower surface of the cathode holder 32b and at equal angular spacing from each other. In this case, the screw hole portions H of the cathode holder 32b may be preferably formed to have a center-to-center spacing d2 of 4 mm to 5 mm.

Accordingly, by setting a position of the screw hole portion H to which the cathode suspension rod 32c is coupled to be different or the same for each cathode holder 32b of each cathode device 32, it is possible to appropriately adjust a spaced distance D of the cathodes N between the cathode devices 32 according to the change of synthesis conditions.

For example, as shown in FIG. 11, the cathode suspension rod 32c of each of the central cathode device 31 and the cathode devices 32 around the central cathode device 32 in the cathode device combination of the cathode portion 30 may be coupled to the screw hole portion H at a central portion of each cathode holder 32b so that the cathodes N can be arranged at a first spaced distance D1 from each other.

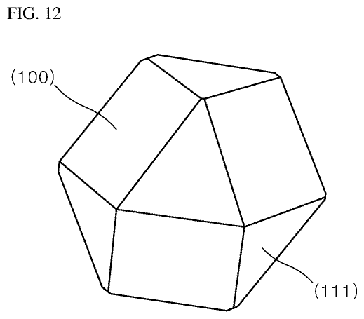

In another example, when the spaced distance D between the cathodes N is required to be adjusted to generate the uniform plasma P as the synthesis conditions for single-crystal diamond are changed, the cathode suspension rod 32c of each of the cathode devices 32 around the central cathode device 31 may be coupled to the screw hole portion H eccentrically positioned in each cathode holder 32b, as shown in FIG. 12, so that the spaced distance D between the cathodes N can be adjusted to a second spaced distance D2 that is different from the first spaced distance D1. In this case, the spaced distance D between the cathodes N may be preferably 35 mm to 50 mm, and the spaced distances D between the cathodes N may be equal to each other.

The process of adjusting the spaced distance D between the cathodes N as described above may be easily performed by separating the top plate 11 on which the cathode portions 30 are installed from the CVD chamber 10. Although in the above-described embodiments the spaced distances D between the cathodes D are described as being adjusted to be equal to each other, the embodiments are not necessarily limited thereto, and the spaced distances D between the cathodes N may be set to be different from each other according to the synthesis conditions for single-crystal diamond.

For SCD growth using the MCDC PACVD apparatus 100 according to one embodiment of the present invention, the single-crystal grit seeds S cleaned with organic materials, such as acetone or alcohol, are seated in the respective seed receiving grooves 71 formed on the stage substrate 70.

Then, in the stage substrate seating step, the stage substrate 70 on which the plurality of single-crystal grit seeds S are seated may be placed into the seating groove portion 21 of the anode portion 20 installed in the inner space A of the CVD chamber 10 and having one end grounded.

Then, in the diamond seed growth step, power is supplied to each cathode N of the cathode portions 30 which is connected to each of the DC power supply devices independent of each other under a predetermined condition, so that DC power plasma P is formed between the cathode portions 30 and the stage substrate 70, thereby growing the single-crystal grit seeds S seated on the stage substrate 70.

In this case, to enable sustained three-dimensional growth of the single-crystal grit seed S, process conditions for the dominant growth of the (100) plane without secondary nucleation on the surface of the single-crystal grit seed S has to be applied, as described above. Also, the growth of the (100) plane must be performed in the near <100> orientation or the near <110> orientation.

To this end, in the deposition step, a mixture of hydrogen, which is a carrier gas, and hydrocarbon gas, which is a carbon supply gas, for example, methane gas (CH₄), may be introduced as a source gas into the CVD chamber 10 at a rate ranging from 10 sccm to 1000 sccm and a process pressure inside the CVD chamber 10 is maintained to be in a range from 10 Torr to 500 Torr. At this time, the composition of methane in the gas mixture may be in a range of 5 to 20% by volume depending on the deposition temperature.

According to an embodiment of the present invention, small-sized single-crystal diamond grits may be grown three-dimensionally to produce SCD particles. In addition, according to the MCDC PACVD apparatus 100 and the growth method proposed by the present embodiment, it is possible to increase the growth rate of the single-crystal diamond more than two times faster than the conventional method by using the MCDC PACVD using a plurality of cathodes N. Also, the arrangement and the protruding height h of the single-crystal grit seeds S seated on the stage substrate 70 are optimized and the control of spaced distances among the cathodes N is easily performed according to the change of growth conditions to improve plasma uniformity, so that the plurality of single-crystal diamond particles can be uniformly grown simultaneously.

Hereinafter, experimental examples are provided to assist in understanding the present invention. The experimental examples provided herein are to assist in understanding the present invention and the present invention is not limited to the following experimental examples.

### Experimental Example 1

As a primary preliminary experiment, the change in texture according to the deposition temperature and the composition of the methane gas, which are main synthetic variables of texture formation in general thin film diamond synthesis, was observed using a DC PACVD device which uses a cathode at a high temperature of 2000° C. or higher. A molybdenum plate was used as a substrate. A mixture gas of a hydrogen gas and a methane gas was used as a source gas, wherein the composition of methane in the mixture gas was maintained at a ratio of 10% by volume. The amount of power input during deposition was 12 kW. A chamber pressure during the process was maintained at 100 Torr, and the deposition temperatures for each sample were 1200° C., 1240° C. 1280° C., and 1320° C. Here, the deposition temperature is a temperature of a stage substrate measured using a pyrometer during the deposition. At the temperature applied, due to the effect of emission generated at the cathode at a high temperature of over 2000° C., the temperature is measured to be about 300° C. or more higher than an actual temperature, and thus the deposition temperature in the present experimental example may be defined as an apparent deposition temperature that indicates the magnitude of relative temperature due to the use of the pyrometer, and the same will apply to other experimental examples below.

(A) to (D) of FIG. 1 are results of observing a surface of a sample at 1200° C., 1240° C., 1280° C., and 1320° C., respectively, with a scanning electron microscope, and (E) of FIG. 1 shows a definition of a crystal orientation. Table 1 shows texture results of diamond crystals according to the apparent deposition temperature.

TABLE 1

| Apparent deposition | |
|---|---|
| Temperature (° C.) | texture |
| (A) 1200 | <100> |
| (B) 1240 | Near <100> |
| (C) 1280 | Near <110> |
| (D) 1320 | <110> |

Referring to FIG. 1 and Table 1, the texture of diamond crystals generated as the apparent deposition temperature was increased from 1200° C. to 1320° C. was changed regularly in the order of <100> orientation, near <110> orientation, near <110> orientation, and <110> orientation. In the present invention, ideal near <100> texture and near <110> texture were observed at 1240° C. to 1280° C. However, this temperature range is sensitive to composition, may be changed according to input power, pressure, and gas flow rate, and may vary according to a diamond synthesis device or temperature measuring equipment used.

### Experimental Example 2

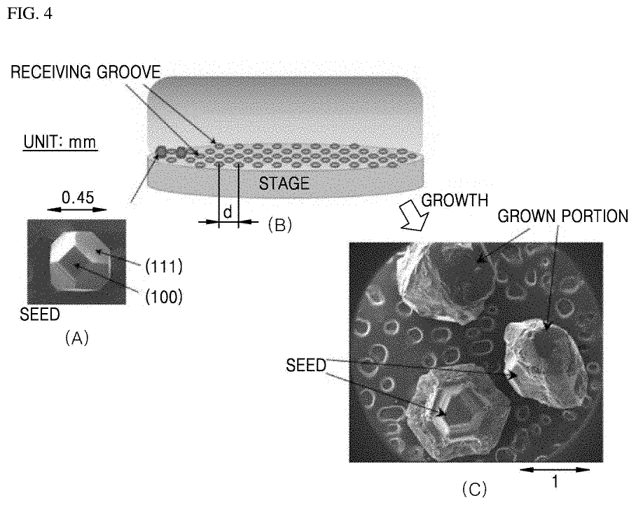

As a secondary preliminary experiment, a secondary nucleation behavior according to a crystal plane was observed using HPHT single-crystal diamond grits (product of General Electric Co.) with a cuboctahedron shape as seeds. The size (diameter) of the single-crystal grit seeds was 0.45 mm ((A) of FIG. 4). After the seeds were seated on receiving grooves of a stage substrate, the stage substrate was placed in a seating groove portion of an anode portion disposed inside of a chamber. Next, a vacuum was formed to be in 10⁻³ Torr region by using a mechanical vacuum pump. Thereafter, a hydrogen gas was added and DC power was supplied to form plasma, and then pressure was gradually increased and maintained at 100 Torr. During deposition, 200 sccm of a mixture gas of a hydrogen gas and a methane gas was added to maintain a process pressure of 100 Torr. The deposition temperature for each sample was 1200° C., 1240° C., 1280° C., and 1320° C., and for each deposition temperature, the composition of methane in the mixture gas was changed to 5%, 10%, 15%, and 20% by volume. The other conditions were the same as in Experimental Example 1. It was checked whether secondary nucleation occurred on the surface of the single-crystal grit seeds by observing the surface of the sample on which the deposition was completed.

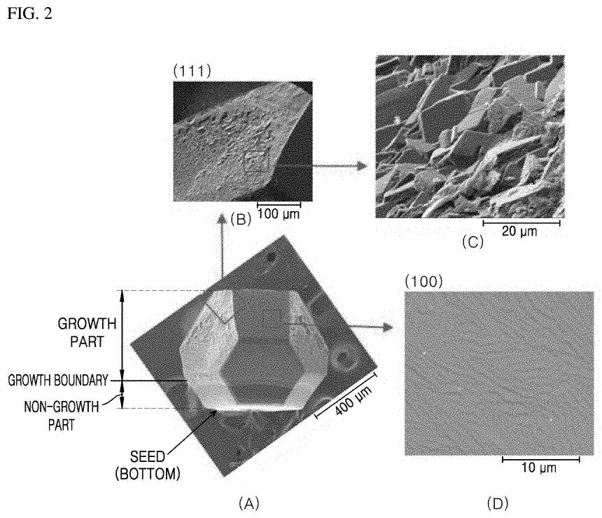

FIG. 2 shows a result of observing with a scanning electron microscope the surface of a sample deposited under conditions of an apparent deposition temperature of 1200° C. (the deposition temperature may vary depending on a diamond synthesis device and a temperature measuring method) and 10% by volume of methane. Specifically, (A) of FIG. 2 is a view observed after a seed was grown, wherein a region (growth part) grown from the seed (non-growth part) is observed and a boundary part (growth boundary) is observed at an interface between the non-growth part and the growth region. The growth part includes (100) plane and (111) plane. In this case, as confirmed in (A), (B), and (C) of FIG. 2, under the pertinent conditions, secondary nucleation occurred at the (111) surface of the growth part and accordingly a number of various crystal planes having facets were generated on the (111) plane. On the contrary, referring to (A) and (D) of FIG. 2, it can be seen that a crystal plane having facets is not observed in the (100) plane of the growth part, but only wave patterns were observed. This confirms that secondary nucleation did not occur on the (100) plane of the growth part.

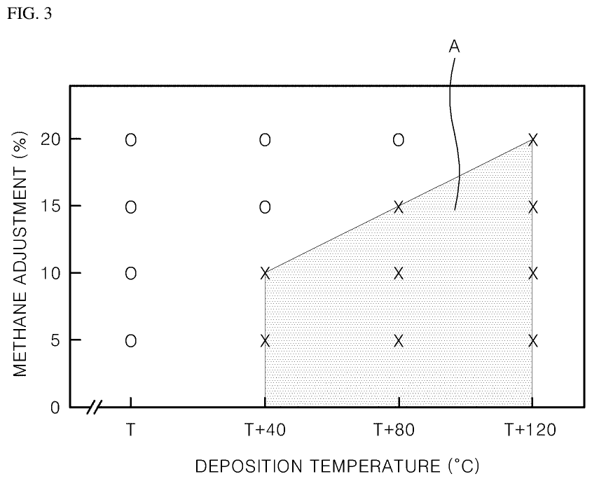

FIG. 3 shows results of confirming whether or not secondary nucleation occurred on (111) plane of each sample formed through single-crystal growth. When a temperature was relatively low, <100> texture was shown. In the present experimental example, a temperature for <100> texture formation was set to T and a relative temperature was provided. For example, in FIG. 3, “T+40” means a temperature 40° C. higher than T. In the present experimental example, temperature T is the apparent deposition temperature of 1200° C.

In FIG. 3, the mark “O” indicates a case where secondary nucleation occurred on the (111) plane, and the mark “X” indicates a case where secondary nucleation did not occur. Referring to FIG. 3, the secondary nucleation on the (111) plane showed a tendency to not occur as the deposition was higher and the composition of methane in the mixture gas was lower. Thus, it can be expected that sustained single-crystal growth is possible when the conditions under which the secondary nucleation on the (111) plane is suppressed are maintained.

An area A where the secondary nucleation on the (111) plane is shown in FIG. 3 and Expression 1 below shows a condition indicating the composition y of methane under which the secondary nucleation on the (111) plane is suppressed according to the area A, i.e., a relative deposition temperature.

y≤0.125(x−40)+5 Expression 1:

y: Volume ratio (%) of methane in a mixture gas

x: T+40 to T+120 (T is a deposition temperature at which <100> texture appears)

That is, a section satisfying the range of Expression 1 is a section in which secondary nucleation does not occur on the (100) plane and (111) plane constituting the surface of the single-crystal diamond grit with a cuboctahedron shape. Thus, the interval may be interpreted as an interval in which SCD of a large size can be produced as the sustained three-dimensional growth is possible.

### Experimental Example 3

Based on the results of Experimental Examples 1 and 2, a particle-shaped SCD growth experiment was conducted using the same DC PACVD diamond growth apparatus. Ten single-crystal grit seeds identical to those used in Experimental Example 1 were each arranged on each of the receiving grooves of a 100-mm-diameter stage substrate ((B) of FIG. 4) made of molybdenum at a predetermined distance to each other, and thereafter the stage substrate was placed inside the chamber. The growth was continued for 30 hours while a temperature of the stage substrate was maintained at 1250° C. to be included in the interval defined by Expression 1, and the other conditions were the same as in Experimental Example 2.

Single-crystal diamond particles and sizes thereof after the growth experiment for 30 hours are shown in (C) of FIG. 4. Referring to (C) of FIG. 4, the sizes (diameters) of the final SCD particles are about 1 mm to 1.5 mm, and it can be seen that the sizes were increased by two to three times compared to a seed shown in (A) of FIG. 4. The weight of the diamond after the growth was increased by about 10 times than before the growth. From these results, it was confirmed that coarse single-crystal diamond in the form of particles could be produced by three-dimensional growth of grit-shaped single-crystal seeds of a relatively small size.

In the embodiment of the present invention, the single-crystal diamond particle is HPHT diamond of 0.5 mm or less in size, but diamond of a larger size or natural diamond may also be possible. In this case, the size and spacing of the receiving grooves of the stage substrate may be changed to fit the size of the particles, and the other conditions will be the same as those in the embodiment of the present invention.

According to the embodiments of the present invention, it is possible to produce particle-shaped single-crystal diamond having industrially or commercially significant size, for example, about 5 mm, by growing SCD grits of relatively fine size. The SCD particles thus produced may be applied not only to industrial application, such as tools, but also to diamond for jewelry, and such particle-shaped single-crystal diamond may be produced efficiently at a lower cost than the conventional HPHT method. Also, since the present invention allows three-dimensional growth, it is possible to provide a method of expanding the area of single-crystal diamond. In addition, it is possible to solve a problem of the loss of diamond occurred in the process of cutting conventional plate-shaped SCDs into pieces of about 5 mm. However, the scope of the present invention is not limited to the above-described effects.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A method of producing a particle-shaped single-crystal diamond (SCD) using chemical vapor deposition (CVD), the method comprising:
disposing a seed on a stage substrate in a vacuum chamber; and
three-dimensionally growing the seed to a particle-shaped SCD by introducing a source gas into the vacuum chamber,
wherein the seed has a cuboctahedron shape consisting of (100) and (111) planes and
the growth of the seed occurs under a condition of near <100> texture or near <110> texture, where (100) planes of diamond grows dominantly and are free from secondary nucleation.

2. The method of claim 1, wherein the seed is a high pressure-high temperature (HPTH) diamond grit, or natural diamond.

3. The method of claim 1, wherein the substrate has a plurality of grooves for seeds to be disposed at a predetermined spacing from one another.

4. The method of claim 1, wherein the disposing of the seed on the stage substrate in the vacuum chamber comprises disposing the seed in the groove such that the seed protrudes from a top surface of the stage substrate in a direction of an upper portion.

5. The method of claim 1, wherein the source gas is a mixture gas of a hydrogen gas and a hydrocarbon gas and a composition of the hydrocarbon gas in the mixture gas is in a range from 1% by volume to 20% by volume.

6. The method of claim 1, wherein the growing to the particle-shaped diamond single-crystal is performed under condition represented by Expression 1 below,
y≤0.125(x−40)+5 Expression 1:
y: Volume ratio (%) of methane in a mixture gas
x: T+40 to T+120 (T is a deposition temperature at which the <100> texture appears).

7. The method of claim 5, a pressure of the vacuum chamber after the source gas is introduced is in a range from 10 Torr to 500 Torr.

8. The method of claim 5, wherein a flow rate of the source gas is in a range from 10 sccm to 1,000 sccm

9. The method of claim 5, wherein the vacuum chamber is a CVD chamber having an inner space formed in which direct current (DC) power plasma is generated between an anode portion and a cathode portion consisting of a plurality of cathodes to synthesize diamond.

10. The method of claim 3, wherein the spacing of the grooves is 1 mm or more.
